(19) United States
(12) Patent Application Publication
(10) Pub. No.: US 2008/0230801 A1
(43) Pub. Date: Sep. 25, 2008

(54) TRENCH TYPE POWER SEMICONDUCTOR DEVICE AND METHOD FOR MANUFACTURING SAME

(76) Inventors: Atsushi MURAKOSHI, Kanagawa-ken (JP); Noboru MATSUDA, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/050,201

(22) Filed: Mar. 18, 2008

(30) Foreign Application Priority Data
Mar. 19, 2007 (JP) 2007-070006

(51) Int. Cl. H01L 29/739; H01L 21/331

(52) U.S. Cl. 257/172; 438/133; 257/E29.197; 257/E21.382

(57) ABSTRACT

A method for manufacturing a trench type power semiconductor device is provided. The method includes: forming a first silicon oxide film on a silicon substrate; forming a thermal oxidation-resistant film on the first silicon oxide film; forming an opening in the first silicon oxide film and the thermal oxidation-resistant film; forming a sidewall on an inner side surface of the opening; forming a trench in the silicon substrate by etching the silicon substrate using the first silicon oxide film, the thermal oxidation-resistant film, and the sidewall as a mask; removing the sidewall; forming a second silicon oxide film thicker than the first silicon oxide film on an inner surface of the trench by applying thermal oxidation to the silicon substrate; burying a trench gate electrode in the trench; removing the thermal oxidation-resistant film; and introducing impurities into at least part of a region of the silicon substrate between the trenches.

### CROSS-REFERENCE TO RELATED APPLICATIONS

This application is based upon and claims the benefit of priority from the prior Japanese Patent Application No. 2007-070006, filed on Mar. 19, 2007; the entire contents of which are incorporated herein by reference.

### BACKGROUND OF THE INVENTION

1. Field of the Invention

This invention relates to a trench type power semiconductor device and a method for manufacturing the same.

2. Background Art

In power semiconductor devices such as an IGBT (insulated gate bipolar transistor) and a power MOSFET (metal oxide semiconductor field effect transistor), a technique for forming a trench gate electrode in the substrate is proposed for reducing ON resistance (see, e.g., M. Usui et al., “Light Emission Analysis of Trench Gate Oxides of Power Devices”, R&D Review of Toyota CRDL, Vol. 39, No. 4, pp. 17-21, hereinafter referred to as Non-patent literature 1).

FIG. 14 is a cross-sectional view showing a conventional trench type power semiconductor device.

As shown in FIG. 14, a conventional trench type power semiconductor device 101 has a trench 103 formed from the upper surface side of a silicon substrate 102. A thermal oxide film 104 is formed on the upper surface of the silicon substrate 102 and on the inner surface of the trench 103. Polysilicon is buried inside the trench 103 to constitute a trench gate electrode 105. Here, the thermal oxide film 104 serves as a gate insulating film. Furthermore, the upper surface of the trench gate electrode 105 is covered with a cap insulating film 106. On the other hand, the region of the silicon substrate 102 located between the trench gate electrodes 105 constitutes a mesa 107. The mesa 107 is selectively doped with acceptors (p-type impurities) to form a p-type base layer 108. Part of the top portion of the p-type base layer 108 is selectively doped with donors (n-type impurities) to form an n-type emitter layer 109.

However, this conventional semiconductor device has the following problems. The power semiconductor device requires high breakdown voltage performance in addition to low ON resistance. Hence the thermal oxide film 104 needs to have a thickness over a certain level. On the other hand, when the thermal oxide film 104 is formed, the inside of the trench 103 suffers from insufficient supply of gas needed for oxidation. Hence the thickness of the portion of the thermal oxide film 104 located in the trench 103 is smaller than the thickness of its portion located on the silicon substrate 102. Furthermore, also inside the trench 103, its lower portion is thinner than its upper portion. Therefore, if the portion of the thermal oxide film 104 located on the bottom of the trench 103 is formed thick enough to ensure sufficient breakdown voltage, the portion of the thermal oxide film 104 located on the silicon substrate 102 ends up being considerably thickened.

Consequently, when the n-type emitter layer 109 is formed, donors are implanted through the thick thermal oxide film 104 formed on the silicon substrate 102. Hence the acceleration voltage during donor implantation needs to be increased. This increases the cost of the facility for donor implantation. Furthermore, donor implantation at high energy damages the thermal oxide film 104, decreasing the breakdown voltage. In particular, as described in Non-patent literature 1, electric field concentrates on the shoulder of the trench 103. Hence any damage to the thermal oxide film 104 covering this shoulder significantly decreases the breakdown voltage. As a method for avoiding this, it is considered to form the n-type emitter layer 109 previously, followed by forming the trench 103. However, in this method, when the thermal oxide film 104 is formed, a highly doped n-type emitter layer 109 is exposed to the side surface of the trench 103, and this exposed surface is oxidized. Hence impurities such as P (phosphorus), As (arsenic), or Sb (antimony) contained in the n-type emitter layer 109 are shattered by thermal oxidation reaction and trapped into the thermal oxide film 104. This results in insufficient breakdown voltage. Furthermore, the shattered impurities are adsorbed on the inner wall of the trench 103 and become a factor of inverting the p-type base layer 108, hence potentially contributing to the malfunction of the semiconductor device.

### SUMMARY OF THE INVENTION

According to an aspect of the invention, there is provided a method for manufacturing a trench type power semiconductor device, including: forming a first silicon oxide film on a silicon substrate; forming a thermal oxidation-resistant film on the first silicon oxide film; forming an opening in the first silicon oxide film and the thermal oxidation-resistant film; forming a sidewall on an inner side surface of the opening; forming a trench in the silicon substrate by etching the silicon substrate using the first silicon oxide film, the thermal oxidation-resistant film, and the sidewall as a mask; removing the sidewall; forming a second silicon oxide film thicker than the first silicon oxide film on an inner surface of the trench by applying thermal oxidation to the silicon substrate; burying a trench gate electrode in the trench; removing the thermal oxidation-resistant film; and introducing impurities into at least part of a region of the silicon substrate between the trenches.

According to another aspect of the invention, there is provided a trench type power semiconductor device including: a silicon substrate; a trench formed in the silicon substrate; a first silicon oxide film formed on a region of the silicon substrate between the trenches; a second silicon oxide film formed on an inner surface of the trench; a trench gate electrode buried in the trench; and an impurity-introduced region formed in at least part of a region of the silicon substrate between the trenches, the first silicon oxide film being thinner than the second silicon oxide film, and a shoulder of the trench being rounded.

### BRIEF DESCRIPTION OF THE DRAWINGS

FIG. 1 is a cross-sectional view illustrating a trench type power semiconductor device according to an embodiment of the invention;

FIG. 2A and FIG. 2B are process cross-sectional views illustrating a method for manufacturing a trench type power semiconductor device according to this embodiment;

FIG. 3A and FIG. 3B are process cross-sectional views illustrating a method for manufacturing a trench type power semiconductor device according to this embodiment;

FIG. 4A and FIG. 4B are process cross-sectional views illustrating a method for manufacturing a trench type power semiconductor device according to this embodiment;

FIG. 5A and FIG. 5B are process cross-sectional views illustrating a method for manufacturing a trench type power semiconductor device according to this embodiment;

FIG. 6A and FIG. 6B are process cross-sectional views illustrating a method for manufacturing a trench type power semiconductor device according to this embodiment;

FIG. 7A and FIG. 7B are process cross-sectional views illustrating a method for manufacturing a trench type power semiconductor device according to this embodiment;

FIG. 8 is a process cross-sectional view illustrating a method for manufacturing a trench type power semiconductor device according to this embodiment;

FIG. 9A and FIG. 9B are process cross-sectional views illustrating a method for manufacturing a trench type power semiconductor device according to a comparative example;

FIG. 10A and FIG. 10B are process cross-sectional views illustrating a method for manufacturing a trench type power semiconductor device according to this comparative example;

FIG. 11A and FIG. 11B are process cross-sectional views illustrating a method for manufacturing a trench type power semiconductor device according to this comparative example;

FIG. 12A and FIG. 12B are process cross-sectional views illustrating a method for manufacturing a trench type power semiconductor device according to this comparative example;

FIG. 13A and FIG. 13B are process cross-sectional views illustrating a method for manufacturing a trench type power semiconductor device according to this comparative example; and

FIG. 14 is a cross-sectional view showing a conventional trench type power semiconductor device.

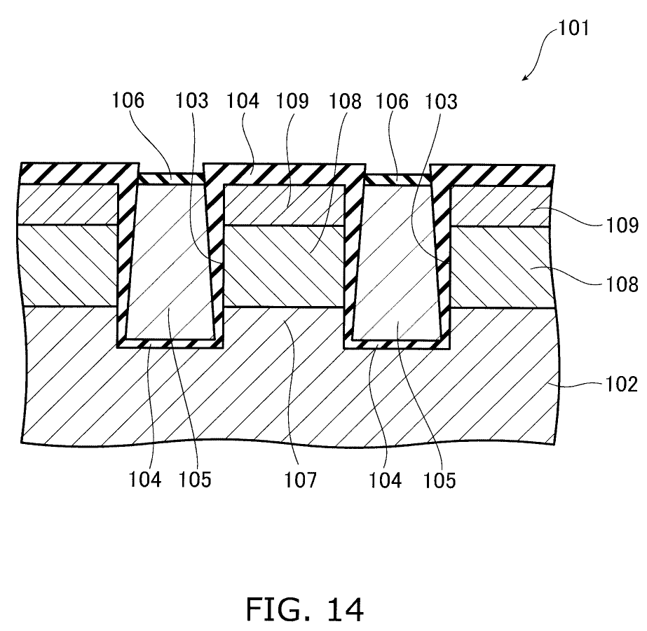

### DETAILED DESCRIPTION OF THE INVENTION

An embodiment of the invention will now be described with reference to the drawings.

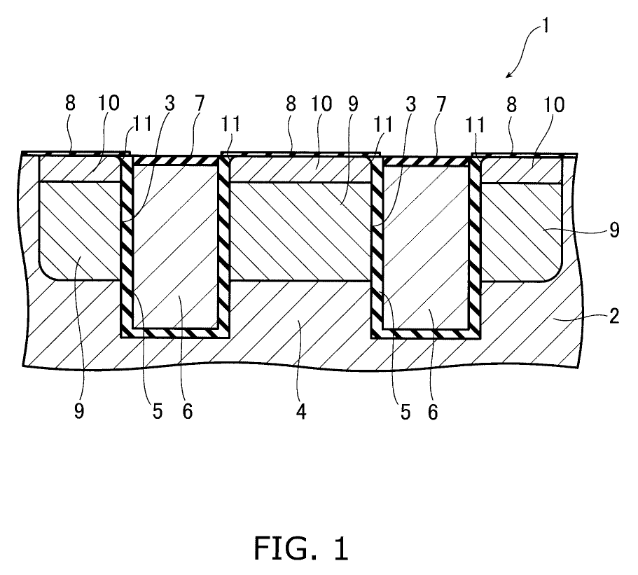

FIG. 1 is a cross-sectional view illustrating a trench type power semiconductor device according to this embodiment.

As shown in FIG. 1, the trench type power semiconductor device 1 (hereinafter simply referred to as “semiconductor device 1”) according to this embodiment is an IGBT or a power MOSFET.

The semiconductor device 1 includes a silicon substrate 2. A plurality of striped trenches 3 are formed in parallel to each other in the upper surface of the silicon substrate 2. The region of the silicon substrate 2 located between the trenches 3 (remaining silicon) constitutes a mesa 4. The mesa 4 serves to pass a current predominantly in the semiconductor device 1.

A gate oxide film 5 of silicon oxide is formed on the inner surface of the trench 3. A trench gate electrode 6 of polysilicon is buried in the trench 3. Thus the trench gate electrode 6 is insulated from the silicon substrate 2 by the gate oxide film 5. The upper surface of the trench gate electrode 6 is recessed relative to the upper surface of the mesa 4, being located below the upper surface of the mesa 4. Furthermore, a post-oxide film 7 of silicon oxide is formed on the upper surface of the trench gate electrode 6.

A buffer oxide film 8 of silicon oxide is formed on the mesa 4. As described later, the gate oxide film 5, the post-oxide film 7, and the buffer oxide film 8 are formed by thermal oxidation of the silicon substrate 2. The mesa 4 is doped with acceptors (p-type impurities) to form a p-type base layer 9. Furthermore, part of the top portion of the p-type base layer 9 is doped with donors (n-type impurities) to form an n-type emitter layer 10. On the other hand, a drain layer (not shown) is formed in the bottom portion of the silicon substrate 2. The conductivity type of the drain layer is p-type in the case of the semiconductor device 1 being an IGBT, and n-type in the case of a power MOSFET.

The thickness of the buffer oxide film 8 formed on the mesa 4 is smaller than the thickness of the gate oxide film 5 formed on the inner surface of the trench 3. The shoulder 11 of the trench 3, that is, the intersection between the inner side surface of the trench 3 and the upper surface of the silicon substrate 2, is rounded.

By way of example, the depth of the trench gate electrode 6 is 6 μm, the depth of the p-type base layer 9 is 4 μm, and the depth of the n-type emitter layer 10 is 0.4 μm (400 nm). The upper surface of the trench gate electrode 6 is located at 0.2 μm (200 nm) below the upper surface of the silicon substrate 2, and the thickness of the post-oxide film 7 is 30 nm. The width of the trench gate electrode 6 is 1.5 μm, and the width of the mesa 4 is 3 μm. The thickness of the buffer oxide film 8 is 10 nm, and the thickness of the gate oxide film 5 is 0.1 μm (100 nm). The curvature radius of the shoulder 11 of the trench 3 is 50 nm. It is noted that the dimensions of each portion in the semiconductor device 1 are not limited to the above numerical example.

In the following, a method for manufacturing a semiconductor device 1 is described.

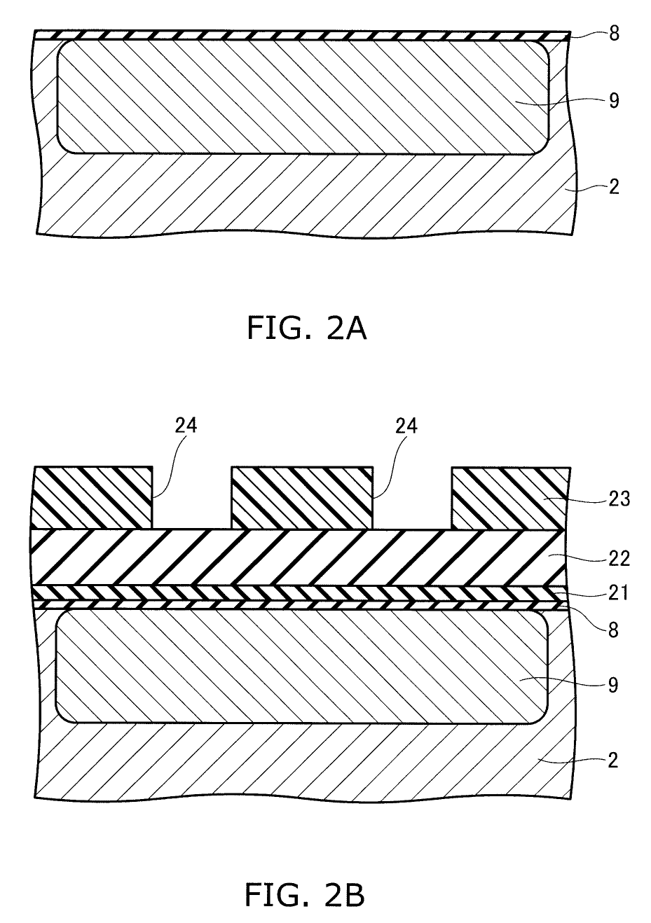

FIGS. 2 to 8 are process cross-sectional views illustrating a method for manufacturing a trench type power semiconductor device according to this embodiment.

First, as shown in FIG. 2A, a silicon substrate 2 of single crystal silicon is prepared. Thermal oxidation is applied thereto to form a thin buffer oxide film 8 on the upper surface of the silicon substrate 2. The buffer oxide film 8 is made of silicon oxide and has a thickness of 10 nm, for example. Next, ion implantation is performed from above the silicon substrate 2. The condition of this ion implantation is illustratively as follows: the ion species is boron (B), the acceleration voltage is 80 keV, and the dose amount is 4.5×10¹³ cm−². Next, the silicon substrate 2 is heated to a temperature of 1100° C. for 60 minutes in a nitrogen atmosphere to diffuse the implanted boron. Thus a p-type base layer 9 having a thickness of 4 μm, for example, is formed in part of the top portion of the silicon substrate 2. On the other hand, impurities are implanted also into the lower surface of the silicon substrate 2 to form a drain layer (not shown).

Next, as shown in FIG. 2B, silicon nitride (SiN) is deposited on the buffer oxide film 8 to a thickness of 30 nm, for example, by CVD (chemical vapor deposition) to form a silicon nitride film 21 serving as a thermal oxidation-resistant film. Next, silicon oxide is deposited on the silicon nitride film 21 to a thickness of 300 nm, for example, by CVD using TEOS (tetraethyl orthosilicate, Si(OC₂H₅)₄) as raw material to form a film-like mask material 22. Next, the upper surface of the mask material 22 is coated with a photoresist, which is patterned by exposure and development to form a resist film 23. At this time, striped openings 24 are formed in the resist film 23 at regions where trenches 3 (see FIG. 1) are to be formed. The width of the opening 24 is 1.2 μm, for example.

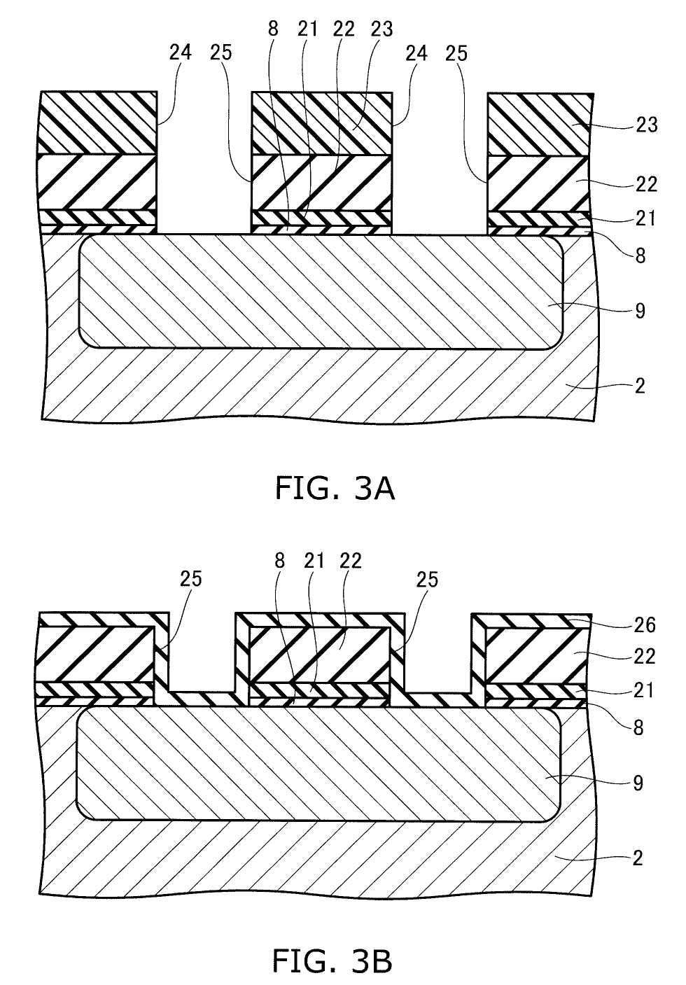

Next, as shown in FIG. 3A, dry etching is performed using the resist film 23 as a mask to continuously process the mask material 22, the silicon nitride film 21, and the buffer oxide film 8. Thus an opening 25 is formed in the region of the silicon nitride film 21, the mask material 22, and the buffer oxide film 8 located directly below the opening 24, that is, in the region where a trench 3 is to be formed. Subsequently, the resist film 23 is removed.

Next, as shown in FIG. 3B, silicon oxide is deposited to a thickness of 50 nm, for example, by CVD using TEOS as raw material to form a film-like spacer mask material 26 entirely on the silicon substrate 2. Thus, temporarily, the openings 25 are partially buried back.

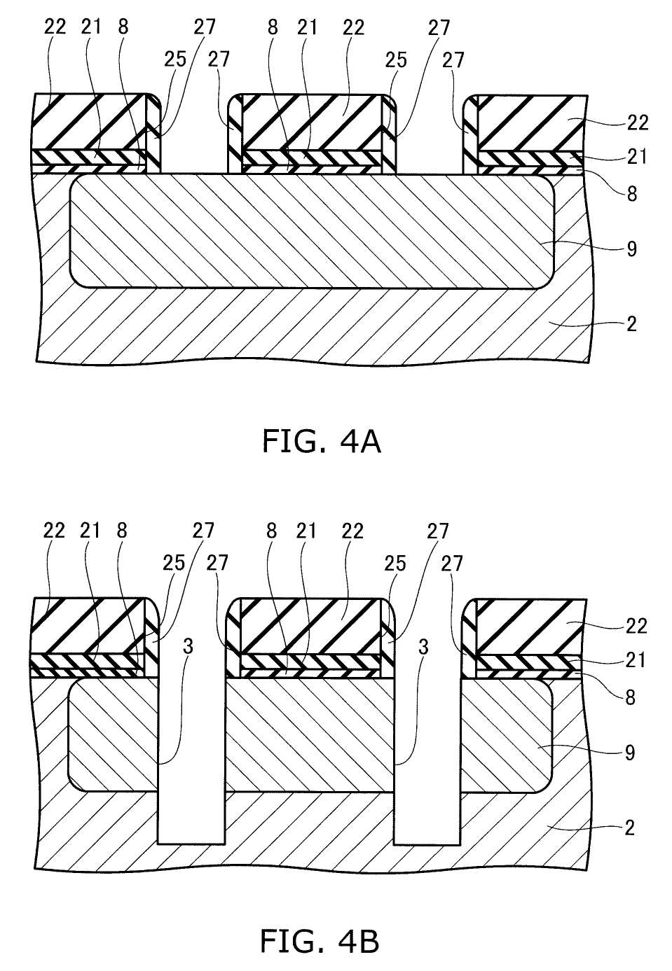

Next, as shown in FIG. 4A, dry etching is performed from above to etch back the spacer mask material 26 (see FIG. 3B) by the amount corresponding to a thickness of 50 nm. Thus the portions of the spacer mask material 26 formed on the upper surface of the mask material 22 and on the bottom surface of the opening 25 are removed. Consequently, the upper surface of the mask material 22 is exposed, and the upper surface of the silicon substrate 2 in the opening 25 is exposed. On the other hand, the portion of the spacer mask material 26 formed on the inner side surface of the opening 25 remains, although with some variation in thickness, and constitutes a sidewall 27.

Next, as shown in FIG. 4B, the sidewall 27 and the laminated body composed of the buffer oxide film 8, the silicon nitride film 21, and the mask material 22 are used as a mask to perform dry etching. The etching condition at this time is determined so that the etching rate of silicon is higher than the etching rate of silicon oxide. Thus the silicon substrate 2 is selectively removed to form a trench 3 having a depth of 6 μm, for example, in the region of the opening 25 where the sidewall 27 is not formed. Here, the region of the silicon substrate 2 located between the trenches 3 constitutes a mesa 4.

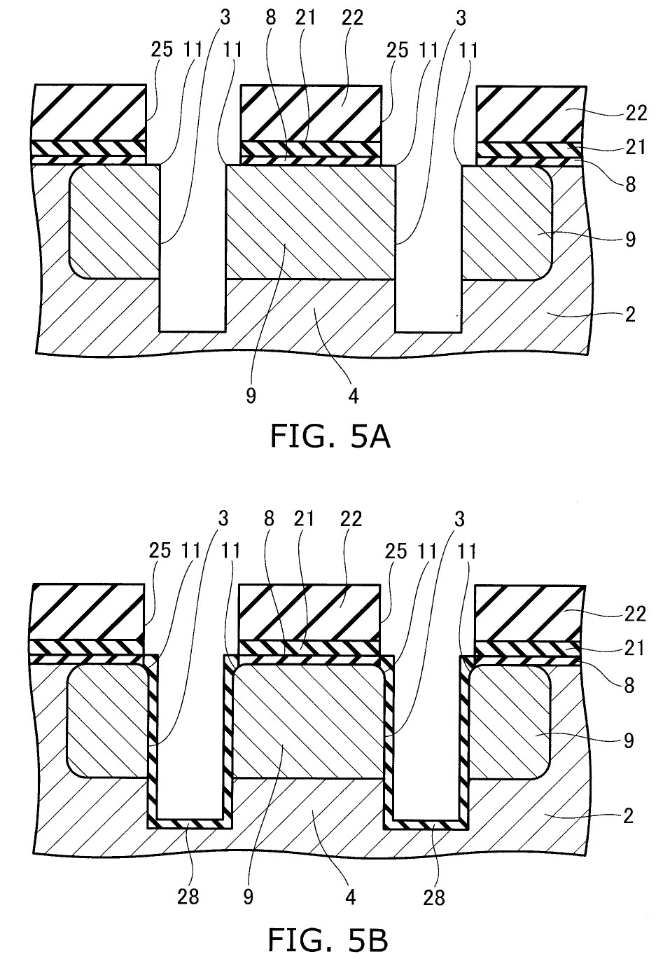

Next, as shown in FIG. 5A, wet etching is performed using a hydrofluoric acid-based etchant to remove the sidewall 27 (see FIG. 4B). Thus the shoulder 11 of the trench 3, that is, the zonal region of the upper surface of the silicon substrate 2 that was covered with the sidewall 27 is exposed. The width of this zonal region is 50 nm, for example. The mask material 22 is also slightly etched in this wet etching, but remains even after the sidewall 27 is completely removed, because the mask material 22 is thicker than the sidewall 27. However, depending on the etching time, the portion of the buffer oxide film 8 and the mask material 22 exposed to the inner side surface of the opening 25 is etched, and the silicon nitride film 21 may protrude like an eaves. In this case, after wet etching, hot phosphoric acid (hot H₃PO₄) treatment is illustratively performed to set back the protrusion of the silicon nitride film 21.

Next, as shown in FIG. 5B, thermal oxidation is performed to form a sacrificial oxide film 28 of silicon oxide on the inner surface of the trench 3. The sacrificial oxide film 28 is formed for removing the damage to the inner surface of the trench 3 associated with dry etching and has a thickness of 50 nm, for example. At this time, the shoulder 11 of the trench 3 is more highly oxidized than the rest of the silicon substrate 2 because its two surfaces, or the upper surface and the side surface, are exposed, and the corner of the unoxidized portion is rounded. It is noted that before this thermal oxidation process, CDE (chemical dry etching) may be performed to thinly remove the inner surface layer of the trench 3.

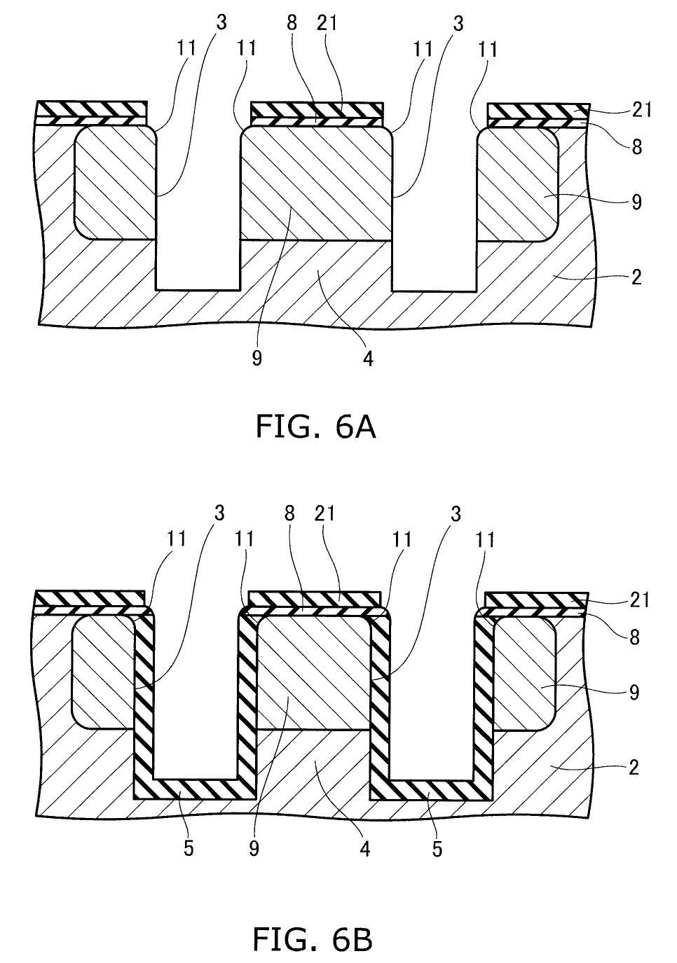

Next, as shown in FIG. 6A, wet etching is performed using a hydrofluoric acid-based etchant to remove the sacrificial oxide film 28 and the mask material 22 (see FIG. 5B). Thus the damage to the inner surface of the trench 3 is also removed. At this time, the buffer oxide film 8 and the silicon nitride film 21 remain above the mesa 4. The silicon substrate 2 is exposed at the inner surface and the shoulder 11 of the trench 3, and the shoulder 11 is rounded.

Next, as shown in FIG. 6B, thermal oxidation is applied to the silicon substrate 2 to form a gate oxide film 5 of silicon oxide on the inner surface of the trench 3. At this time, while the thickness of the gate oxide film 5 decreases as it goes down in the trench 3, the minimum thickness of the gate oxide film 5 is 100 nm, for example. On the other hand, the upper surface of the mesa 4 of the silicon substrate 2 is covered with the silicon nitride film 21 serving as a thermal oxidation-resistant film. Hence there is no additional oxidation of the buffer oxide film 8 or new formation of an oxide film above the mesa 4. Furthermore, at this time, the shoulder 11 is more intensively oxidized than the other portion, and the corner of the unoxidized portion is further rounded. That is, the curvature radius of the shoulder 11 increases.

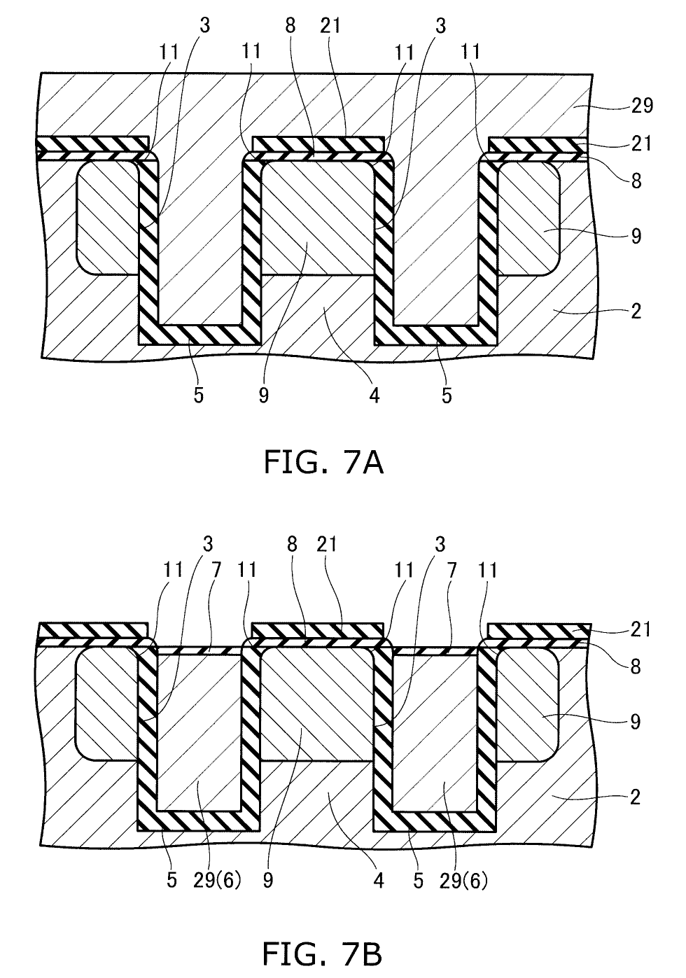

Next, as shown in FIG. 7A, polysilicon doped with phosphorus (P) is deposited entirely on the silicon substrate 2 to form a polysilicon layer 29. Here, the deposited amount of polysilicon is 1 μm, for example. The polysilicon layer 29 is buried in the trench 3 as well as being formed on the silicon nitride film 21.

Next, as shown in FIG. 7B, CDE is performed entirely on the silicon substrate 2 from thereabove to remove the polysilicon layer 29 on the silicon nitride film 21. Here, if the polysilicon layer 29 remains on the silicon nitride film 21, it may cause short circuit between the trench gate electrodes 6. Hence the polysilicon layer 29 on the silicon nitride film 21 needs to be definitely removed. For this reason, the amount of etching is set to result in a slight overetching. Thus the upper portion of the polysilicon layer 29 buried in the trench 3 is also etched away, and the upper surface of the polysilicon layer 29 is recessed relative to the upper surface of the mesa 4. Here, the recessed amount is 0.2 μm, for example. That is, the upper surface of the polysilicon layer 29 is located at e.g. 0.2 μm below the upper surface of the silicon substrate 2.

Next, thermal oxidation is performed again to form a thermal oxide film having a thickness of 30 nm, for example, on the upper surface of the polysilicon layer 29 buried in the trench 3. This thermal oxide film constitutes a post-oxide film 7 for capping the polysilicon layer 29. The polysilicon layer 29 buried in the trench 3 and insulated from the silicon substrate 2 by the gate oxide film 5 and the post-oxide film 7 constitutes a trench gate electrode 6. Also in the step of forming the post-oxide film 7, the upper surface of the mesa 4 is covered with the silicon nitride film 21, and hence there is no additional oxidation of the buffer oxide film 8 or new formation of an oxide film on the mesa 4. Here, the silicon nitride film 21 is exposed to an oxidizing atmosphere in the thermal oxidation steps shown in FIGS. 6B and 7B. Hence, at this stage, its superficial portion is oxidized to some extent to constitute a silicon oxynitride layer.

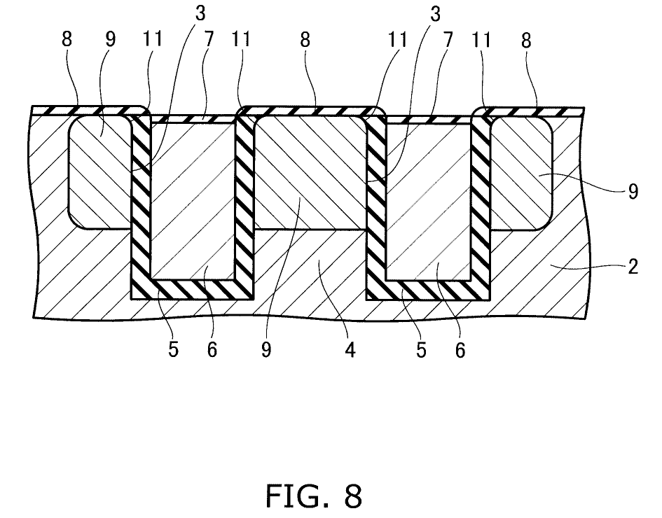

Next, as shown in FIG. 8, wet etching is performed using a hydrofluoric acid-based etchant to remove the silicon oxynitride layer formed in the superficial portion of the silicon nitride film 21. Subsequently, hot phosphoric acid (hot H₃PO₄) treatment is illustratively performed to remove the silicon nitride film 21. Thus only the buffer oxide film 8 having a thickness of 10 nm, for example, remains on the mesa 4.

Next, as shown in FIG. 1, ion implantation of arsenic (As) serving as donors is performed from above the silicon substrate 2 through the buffer oxide film 8, and then thermal diffusion is performed. Thus an n-type emitter layer 10 is formed in part of the upper portion of the p-type base layer 9. At this time, in order to drive the n-type emitter layer 10 by the potential of the trench gate electrode 6, the depth of the n-type emitter layer 10 needs to be larger than the recessed amount of the trench gate electrode 6, that is, the distance between the upper surface of the silicon substrate 2 and the upper surface of the trench gate electrode 6. In this embodiment, the recessed amount of the trench gate electrode 6 is 0.2 μm, for example. Hence the depth of the n-type emitter layer 10 is 0.4 μm, for example. To this end, for example, the acceleration voltage for implanting arsenic ions is 70 keV, and the thermal diffusion is performed by RTA (rapid thermal anneal) with a temperature of 1000° C. and a time of 30 seconds. The semiconductor device 1 is manufactured by the foregoing process.

Next, the operation and effect of this embodiment are described.

As described above, in the method for manufacturing a semiconductor device 1 according to this embodiment, a silicon nitride film 21 is formed as a thermal oxidation-resistant film on the buffer oxide film 8 in the step shown in FIG. 2B. Thus there is no additional oxidation of the buffer oxide film 8 or new formation of a thermal oxide film on the mesa 4 in the thermal oxidation step for forming the gate oxide film 5 shown in FIG. 6B and the thermal oxidation step for forming the post-oxide film 7 shown in FIG. 7B. Hence the buffer oxide film 8 can be kept thin even if the gate oxide film 5 is formed thick enough to ensure sufficient breakdown voltage. That is, the thickness of the buffer oxide film 8 and the thickness of the gate oxide film 5 can be controlled independently, and the gate oxide film 5 can be formed thicker than the buffer oxide film 8. Consequently, a low acceleration voltage can be used in implanting impurity ions through the buffer oxide film 8 as shown in FIG. 1. In this embodiment, arsenic serving as donors is implanted at an acceleration voltage of 70 keV to form an n-type emitter layer 10 having a junction depth of 0.4 μm. Thus the cost of the facility for ion implantation can be held down, and the cost of manufacturing the semiconductor device 1 can be reduced.

According to this embodiment, impurity ions can be implanted into a sufficiently deep position at a low acceleration voltage. Hence the adjustment range of temperature and time in the thermal diffusion process can be expanded. That is, in forming the impurity diffusion layer, constraints on the acceleration energy for ion implantation and the thermal budget of thermal diffusion can be reduced, and the process window can be expanded. This facilitates combination of conditions concerning the ion implantation step and the thermal step in the process for manufacturing a trench type power semiconductor device. Furthermore, flexibility in the process design is increased because the condition for forming the gate oxide film and the condition for forming the impurity diffusion layer can be determined independently.

Furthermore, by using a low acceleration voltage in implanting impurity ions, damage to the gate oxide film 5 due to impurity implantation can be prevented. Thus the breakdown voltage of the semiconductor device 1 can be prevented from decreasing.

Moreover, in this embodiment, a sidewall 27 is formed on the inner side surface of the opening 25 in the steps shown in FIGS. 3B and 4A, a trench 3 is formed by using the sidewall 27 as a mask in the step shown in FIG. 4B, and then the sidewall 27 is removed in the step shown in FIG. 5A. Thus, as shown in FIG. 5A, the silicon substrate 2 can be exposed at the shoulder 11 of the trench 3. In this state, in the steps shown in FIGS. 5B and 6B, the shoulder 11 of the trench 3 can be rounded by thermal oxidation. Consequently, in operation of the semiconductor device 1, concentration of electric field on the shoulder 11 can be prevented to improve the breakdown voltage.

Thus this embodiment can provide a trench type power semiconductor device having a high breakdown voltage at low manufacturing cost.

In the above manufacturing method, it is also considered to use only the technique of forming a thermal oxidation-resistant film to decrease the ion acceleration voltage without using the technique of forming a sidewall to round the shoulder. However, in this case, as a consequence of forming a thermal oxidation-resistant film, the upper surface of the silicon substrate 2 is covered with the thermal oxidation-resistant film up to the edge of the trench 3 during thermal oxidation. Hence the shoulder 11 is sharpened more prominently than in the case of no thermal oxidation-resistant film, and the decrease of breakdown voltage becomes more serious. Therefore, to avoid this problem, the shoulder needs to be rounded by forming a sidewall.

Next, a comparative example of the invention is described.

The comparative example is different from the above embodiment in that a trench type power semiconductor device is manufactured without forming a thermal oxidation-resistant film and a sidewall.

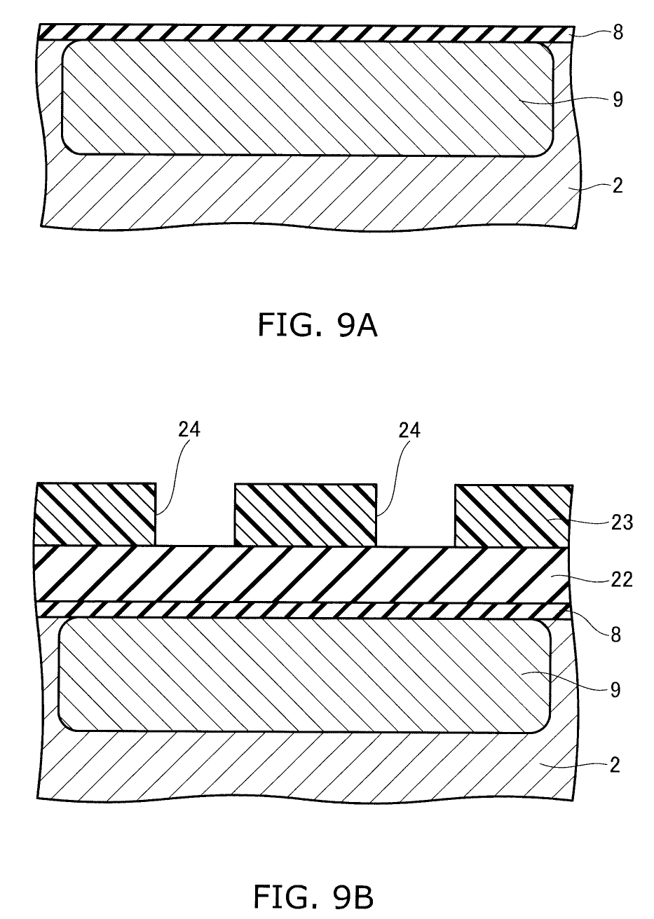

FIGS. 9 to 13 are process cross-sectional views illustrating a method for manufacturing a trench type power semiconductor device according to the comparative example.

In FIGS. 9 to 13, the same components as those in the above embodiment of the invention are marked with like reference numerals and not described in detail.

First, as shown in FIG. 9A, thermal oxidation is applied to a silicon substrate 2 of single crystal silicon to form a buffer oxide film 8 having a thickness of 30 nm, for example, on the upper surface of the silicon substrate 2. Next, ion implantation is performed on the upper surface of the silicon substrate 2, and thermal diffusion is performed to form a p-type base layer 9 having a thickness of 4 μm, for example. The conditions for the ion implantation and the thermal diffusion are the same as those in the above embodiment: for example, the ion species is boron (B), the acceleration voltage is 80 keV, the dose amount is 4.5×10¹³ cm⁻², the thermal processing atmosphere is a nitrogen atmosphere, the temperature is 1100° C., and the time is 60 minutes. On the other hand, impurities are implanted also into the lower surface of the silicon substrate 2 to form a drain layer (not shown).

Next, as shown in FIG. 9B, silicon oxide is deposited on the buffer oxide film 8 to a thickness of 300 nm, for example, by CVD using TEOS as raw material to form a mask material 22. Next, the upper surface of the mask material 22 is coated with a photoresist, which is patterned by exposure and development to form a resist film 23. At this time, striped openings 24 are formed in the resist film 23 at regions where trenches 3 are to be formed. The width of the opening 24 is 1.2 μm, for example. That is, in the comparative example, the mask material 22 is formed directly on the buffer oxide film 8 without forming thereon a silicon nitride film 21 (see FIG. 2B).

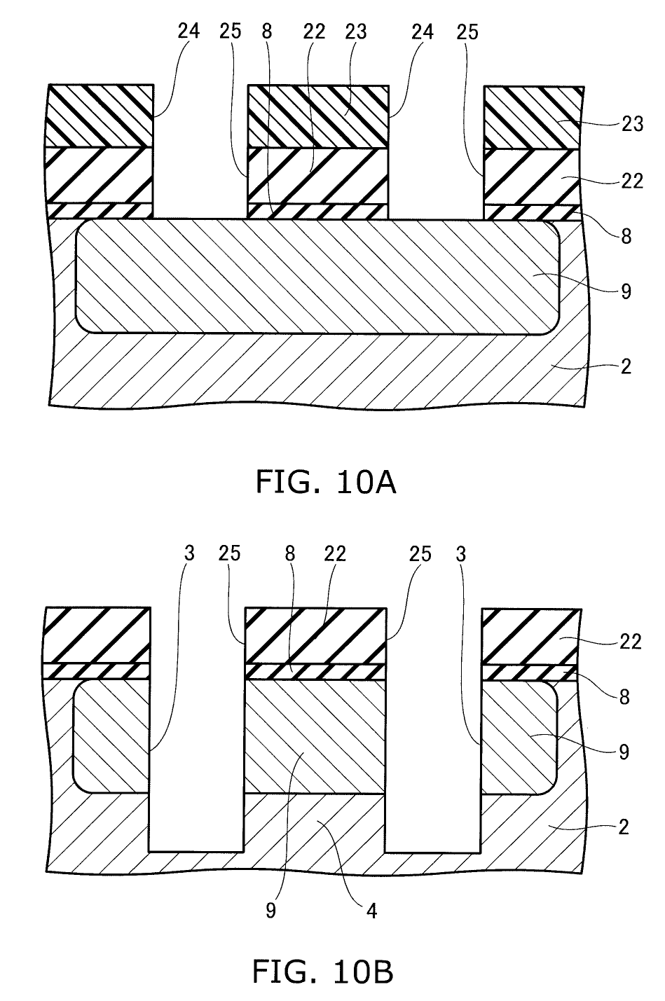

Next, as shown in FIG. 10A, RIE (reactive ion etching) is performed using the resist film 23 as a mask to continuously process the mask material 22 and the buffer oxide film 8. Thus an opening 25 is formed in the region of the mask material 22 and the buffer oxide film 8 located directly below the opening 24. Subsequently, the resist film 23 is removed.

Next, as shown in FIG. 10B, RIE is performed using the mask material 22 as a mask. Thus the silicon substrate 2 is selectively removed to form a trench 3 having a depth of 6 μm, for example, in the region corresponding to the opening 25. Here, the region of the silicon substrate 2 located between the trenches 3 constitutes a mesa 4. Then the exposed portion of the silicon substrate 2 is removed by CDE by a thickness of 50 nm. Thus the damage to the silicon substrate 2 due to RIE is partly removed.

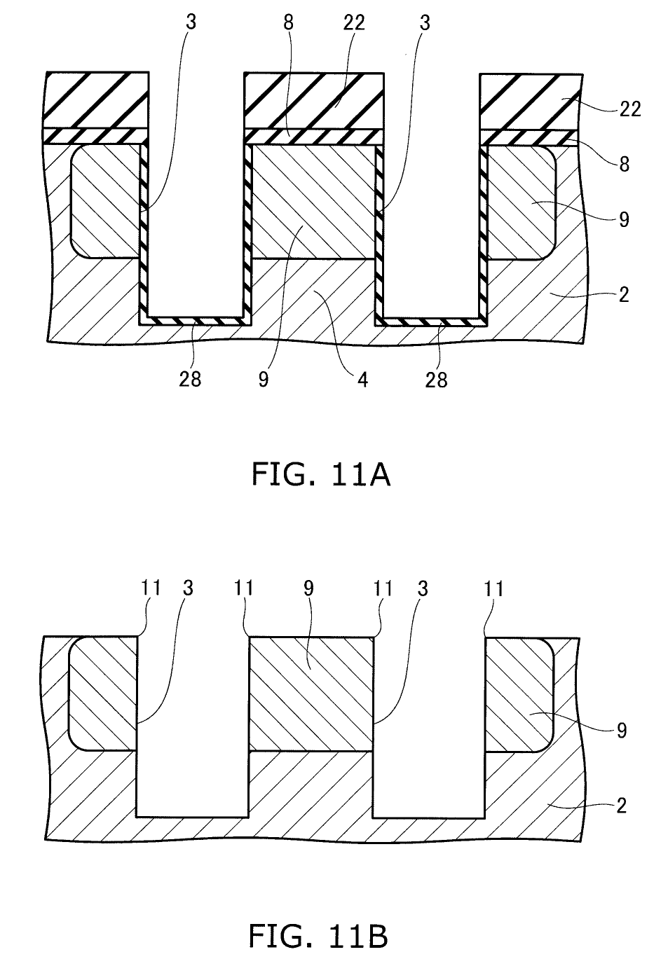

Next, as shown in FIG. 11A, thermal oxidation is performed to form a sacrificial oxide film 28 of silicon oxide on the inner surface of the trench 3. The sacrificial oxide film 28 has a thickness of 50 nm, for example.

Next, as shown in FIG. 11B, wet etching is performed using a hydrofluoric acid-based etchant to remove the mask material 22, the buffer oxide film 8, and the sacrificial oxide film 28. Thus the silicon substrate 2 is exposed, and the damage to the inner surface of the trench 3 is further removed. It is noted that the shoulder 11 of the trench 3 is not rounded, but remains in a sharp configuration.

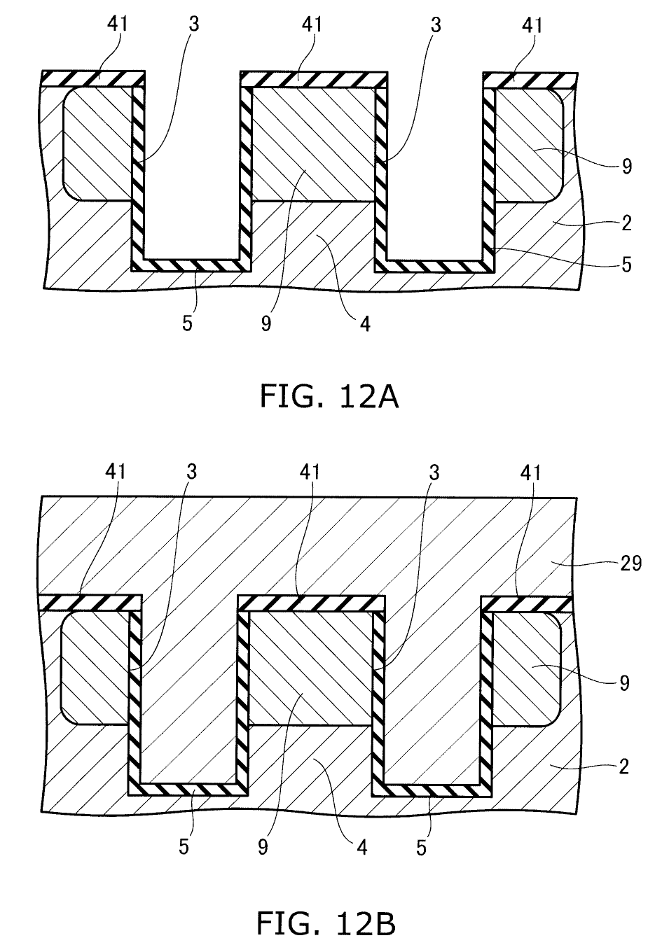

Next, as shown in FIG. 12A, thermal oxidation is performed to form a gate oxide film 5 of silicon oxide on the inner surface of the trench 3. The gate oxide film 5 has a thickness of 100 nm, for example. The thermal processing atmosphere is a dry oxygen atmosphere, and the thermal processing temperature is 1100° C., for example. At this time, a thermal oxide film 41 is formed also on the upper surface of the mesa 4 of the silicon substrate 2. Because the upper surface of the mesa 4 is more likely to be supplied with oxygen than the inside of the trench 3, the thermal oxide film 41 is thicker than the gate oxide film 5 and has a thickness exceeding 100 nm, for example.

Next, as shown in FIG. 12B, polysilicon doped with phosphorus (P) is deposited entirely on the silicon substrate 2 to form a polysilicon layer 29. Here, the deposited amount of polysilicon is 1 μm, for example. The polysilicon layer 29 is buried in the trench 3 as well as being formed on the thermal oxide film 41.

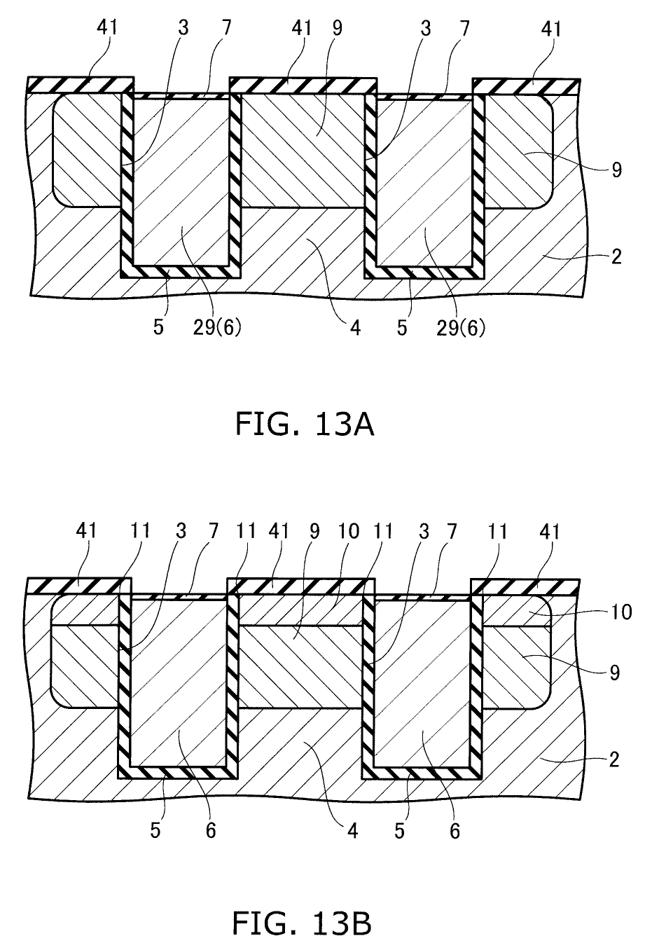

Next, as shown in FIG. 13A, CDE is performed entirely on the silicon substrate 2 from thereabove to remove the polysilicon layer 29 on the thermal oxide film 41. Here, the thermal oxide film 41 is used as an etching end point. The amount of etching is set to result in a slight overetching so that the polysilicon layer 29 does not remain on the thermal oxide film 41. Thus the upper portion of the polysilicon layer 29 buried in the trench 3 is also etched away, and the upper surface of the polysilicon layer 29 is located at e.g. 0.2 μm below the upper surface of the mesa 4.

Subsequently, thermal oxidation is performed again to form a post-oxide film 7 having a thickness of 30 nm, for example, on the upper surface of the polysilicon layer 29 buried in the trench 3. By this thermal oxidation, the thermal oxide film 41 formed on the mesa 4 is additionally oxidized, and its thickness further increases. The polysilicon layer 29 buried in the trench 3 constitutes a trench gate electrode 6.

Next, as shown in FIG. 13B, ion implantation of arsenic (As) serving as donors is performed from above the silicon substrate 2 through the thermal oxide film 41, and then thermal diffusion is performed. Thus an n-type emitter layer 10 is formed in part of the upper portion of the p-type base layer 9. The trench type power semiconductor device according to the comparative example is manufactured by the foregoing process. The dimensions of each portion in this semiconductor device are generally the same as those in the semiconductor device 1 shown in FIG. 1.

In the comparative example, in the step of forming an n-type emitter layer 10 shown in FIG. 13B, ion implantation must be performed through the thick thermal oxide film 41. A dose amount on the order of 10¹⁴ cm⁻² is needed in order for the n-type emitter layer 10 to function as an emitter. Furthermore, in order to drive the n-type emitter layer 10 by the potential of the trench gate electrode 6, the depth of the n-type emitter layer 10 needs to be larger than the recessed amount of the trench gate electrode 6. In the comparative example, the recessed amount of the trench gate electrode 6 is 0.2 μm. Hence the depth of the n-type emitter layer 10 needs to be at least approximately 0.3 to 0.4 μm. Therefore, in the comparative example, an n-type emitter layer 10 having a dose amount on the order of 10¹⁴ cm⁻² and a junction depth of approximately 0.3 to 0.4 μm must be formed by ion implantation through the thermal oxide film 41 having a thickness of 100 nm or more, followed by thermal diffusion.

To this end, the acceleration voltage for ion implantation needs to be 220 keV or more, and the temperature and time of thermal diffusion need to be 950° C. and 60 minutes, or 1000° C. and 30 minutes or more. In contrast, in the above embodiment of the invention, the acceleration voltage for ion implantation is 70 keV, and the thermal diffusion process is RTA with a temperature of 1000° C. and a time of 30 seconds. That is, the comparative example needs ion implantation with higher acceleration voltage and thermal diffusion with higher temperature and longer time than the above embodiment.

Consequently, the comparative example needs a special ion implantation apparatus that can perform ion implantation at high acceleration voltage in order to form an n-type emitter layer 10. On the other hand, currently, with the downscaling of logic semiconductor devices and memory semiconductor devices (hereinafter referred to as “logic/memory semiconductor devices”), the ion implantation voltage for manufacturing such logic/memory semiconductor devices tends to decrease. Furthermore, recently, there has been a demand to share the manufacturing line between power semiconductor devices and logic/memory semiconductor devices in order to reduce facility cost. However, due to the above circumstances, sharing of the manufacturing line is extremely difficult in the comparative example.

In contrast, according to the above embodiment of the invention, the acceleration voltage during ion implantation can be decreased to a level comparable to the acceleration voltage in manufacturing logic/memory semiconductor devices. Hence it is possible to share the manufacturing line between power semiconductor devices according to the embodiment of the invention and typical logic/memory semiconductor devices. Furthermore, it is possible to provide a process highly compatible with the process for manufacturing logic/memory semiconductor devices.

In the comparative example, the need of high-temperature, long-time thermal diffusion increases manufacturing cost, and the need of a special heating furnace increases facility cost and makes it difficult to increase the wafer diameter. Furthermore, it is also difficult to downscale the device structure because of the increased diffusion distance of impurities. In contrast, according to the embodiment of the invention, thermal diffusion is completed in an extremely short time. Hence the time required for the process can be reduced, and the manufacturing cost can be decreased. Furthermore, because a general-purpose heating furnace can be used, it is possible to hold down the facility cost, to downscale the device structure, and to increase the wafer diameter.

In the comparative example, implantation of high-speed ions damages the thermal oxide film 41 and the gate oxide film 5 covering the shoulder 11 of the trench 3. Furthermore, because the configuration of the shoulder 11 remains sharpened, electric field concentrates on this portion. This results in decreasing the overall breakdown voltage of the semiconductor device. In contrast, according to the embodiment of the invention, there is little damage to the gate oxide film 5 because the implanted ions have low speed, and electric field concentration is alleviated because the shoulder 11 is rounded. This results in increasing the breakdown voltage of the semiconductor device.

The gate breakdown voltage was measured for semiconductor devices according to the embodiment of the invention and semiconductor devices according to the comparative example. The obtained breakdown voltage was 53 V or more for the semiconductor devices according to the embodiment of the invention, whereas it was as low as approximately 39 V for the semiconductor devices according to the comparative example. Structural analysis revealed that the breakdown voltage is degraded at the shoulder of the trench. This measurement result demonstrates the above advantageous effect of rounding the shoulder 11.

In the comparative example, in order to reduce the acceleration voltage during ion implantation, it is considered to perform ion implantation after removing the thermal oxide film 41 by wet etching using a hydrofluoric acid-based etchant, for example. This can indeed reduce the acceleration voltage during ion implantation. However, in this case, the gate oxide film 5 formed on the inner side surface of the trench 3 is set back by wet etching, which results in thinning, or eliminating, the gate oxide film 5 covering the shoulder 11. This causes a serious problem of significantly decreasing the gate withstand capability.

It is also considered to remove the thermal oxide film 41 by wet etching or RIE after forming a resist, for example, directly above the trench gate electrode 6 to protect the gate oxide film 5. This can indeed prevent the gate oxide film 5 from being set back. However, in this case, there is a problem of difficult alignment for the trench gate electrode 6 in resist exposure. More specifically, if exposure with an alignment margin of approximately 0.2 μm is required, this precision is difficult to achieve using a general-purpose i-line exposure. For this reason, exposure with DUV (deep ultraviolet) radiation based on KrF/ArF is needed, increasing the facility cost of the exposure apparatus. Furthermore, the number of steps increases due to additional steps of application, exposure, development, and peeling of the resist. This significantly decreases mass productivity and increases manufacturing cost.

The invention has been described with reference to the embodiment. However, the invention is not limited to this embodiment. For example, the above embodiment can be modified appropriately by those skilled in the art through addition, deletion, and/or design change of the components, and such modifications are also encompassed within the scope of the invention as long as they include the features of the invention. For example, while a silicon nitride film is illustratively formed as a thermal oxidation-resistant film in the above embodiment, the invention is not limited thereto. The thermal oxidation-resistant film can be formed from any material that can allow for sufficient etching selection ratio with respect to silicon oxide and silicon. For example, the material may have a lower etching rate than silicon oxide in wet etching for removing silicon oxide, and than silicon in dry etching for removing silicon. Furthermore, for example, the material may be resistant to a hydrofluoric acid-based etchant, and to CDE for processing silicon.

1. A method for manufacturing a trench type power semiconductor device, comprising:
forming a first silicon oxide film on a silicon substrate;
forming a thermal oxidation-resistant film on the first silicon oxide film;
forming an opening in the first silicon oxide film and the thermal oxidation-resistant film;
forming a sidewall on an inner side surface of the opening;
forming a trench in the silicon substrate by etching the silicon substrate using the first silicon oxide film, the thermal oxidation-resistant film, and the sidewall as a mask;
removing the sidewall;
forming a second silicon oxide film thicker than the first silicon oxide film on an inner surface of the trench by applying thermal oxidation to the silicon substrate;
burying a trench gate electrode in the trench;
removing the thermal oxidation-resistant film; and
introducing impurities into at least part of a region of the silicon substrate between the trenches.

2. The method for manufacturing a trench type power semiconductor device according to claim 1, wherein a silicon nitride film is formed as the thermal oxidation-resistant film.

3. The method for manufacturing a trench type power semiconductor device according to claim 1, further comprising:
forming a film-like mask material on the thermal oxidation-resistant film,
wherein the forming an opening includes forming the opening also in the mask material, and
the forming a sidewall includes:
entirely forming a film-like spacer mask material; and
etching back the spacer mask material to leave it only on the inner side surface of the opening.

4. The method for manufacturing a trench type power semiconductor device according to claim 2, further comprising:
forming a film-like mask material on the thermal oxidation-resistant film,
wherein the forming an opening includes forming the opening also in the mask material, and
the forming a sidewall includes:
entirely forming a film-like spacer mask material; and
etching back the spacer mask material to leave it only on the inner side surface of the opening.

5. The method for manufacturing a trench type power semiconductor device according to claim 1, wherein the forming a second silicon oxide film includes rounding a shoulder of the trench.

6. The method for manufacturing a trench type power semiconductor device according to claim 2, wherein the forming a second silicon oxide film includes rounding a shoulder of the trench.

7. The method for manufacturing a trench type power semiconductor device according to claim 3, wherein the forming a second silicon oxide film includes rounding a shoulder of the trench.

8. The method for manufacturing a trench type power semiconductor device according to claim 1, wherein the first silicon oxide film is formed by applying the thermal oxidation to the silicon substrate.

9. The method for manufacturing a trench type power semiconductor device according to claim 1, wherein the thermal oxidation-resistant film is formed by chemical vapor deposition.

10. The method for manufacturing a trench type power semiconductor device according to claim 1, wherein the opening is formed by dry etching.

11. The method for manufacturing a trench type power semiconductor device according to claim 1, wherein the etching for forming the trench is performed under a condition that an etching rate of silicon is higher than an etching rate of silicon oxide.

12. The method for manufacturing a trench type power semiconductor device according to claim 1, wherein the trench gate electrode is formed by burying a polysilicon layer in the trench, the polysilicon layer formed by depositing polysilicon on the silicon substrate.

13. The method for manufacturing a trench type power semiconductor device according to claim 1, wherein the polysilicon layer is etched so that an upper surface of the polysilicon layer is located below an upper surface of the silicon substrate.

14. The method for manufacturing a trench type power semiconductor device according to claim 1, further comprising:
forming a thermal oxide film on the upper surface of the trench gate electrode.

15. The method for manufacturing a trench type power semiconductor device according to claim 1, wherein the introduction of the impurities is performed by implantation of acceptors through the first silicon oxide film to form a p-type base layer.

16. The method for manufacturing a trench type power semiconductor device according to claim 1, wherein the introduction of the impurities is performed by implantation of donors through the first silicon oxide film to form an n-type emitter layer.

17. A trench type power semiconductor device comprising:
a silicon substrate;
a trench formed in the silicon substrate;
a first silicon oxide film formed on a region of the silicon substrate between the trenches;
a second silicon oxide film formed on an inner surface of the trench;
a trench gate electrode buried in the trench; and
an impurity-introduced region formed in at least part of a region of the silicon substrate between the trenches,
the first silicon oxide film being thinner than the second silicon oxide film, and a shoulder of the trench being rounded.

18. The trench type power semiconductor device according to claim 17, further comprising a thermal oxide film being formed on an upper surface of the trench gate electrode.

19. The trench type power semiconductor device according to claim 17, wherein the impurity-introduced region includes a p-type base layer and an n-type emitter layer formed on the p-type base layer.

20. The trench type power semiconductor device according to claim 17, wherein an upper surface of the trench gate electrode is located below an upper surface of the silicon substrate.
